(19) United States
(12) Patent Application Publication
(10) Pub. No.: US 2026/0262461 A1
(43) Pub. Date: Sep. 3, 2026

(54) METHOD FOR PROCESSING A BONDED WAFER AND PROCESSING APPARATUS

(71) Applicant: DISCO CORPORATION, Tokyo (JP)

(72) Inventors: Hiroshi MORIKAZU, Tokyo (JP); Yuki KONISHI, Tokyo (JP); Ryota AOKI, Tokyo (JP); Naoki MURAZAWA, Tokyo (JP)

(21) Appl. No.: 19/454,994

(22) Filed: Jan. 21, 2026

(30) Foreign Application Priority Data
Feb. 28, 2025 (JP) 2025-031617

(51) Int. Cl. H10P 56/00; H10P 34/42

(52) U.S. Cl. CPC H10P 56/00; H10P 34/42

(57) ABSTRACT

A method for processing a bonded wafer where a first wafer, in which a first device layer including first devices and an insulating film arranged in this order from a front surface side is formed on a front surface of a first substrate, and a second wafer are bonded, to transfer the first devices to the second wafer by separating at least the first substrate, includes a deforming step including deforming at least the first substrate such that a position on one side of the first substrate and a position on the other side of the first substrate in a planar direction are different in a direction intersecting with the planar direction; and a separating step including, after the deforming step, separating at least the first substrate leaving the first devices on the second wafer.

### CROSS REFERENCE TO RELATED APPLICATION

This application is based upon and claims the benefit of priority from the prior Japanese Patent Application No. 2025-031617 filed on February 28, 2025; the entire contents of which are incorporated herein by reference.

### FIELD

The present disclosure relates to a method for processing a bonded wafer and a processing apparatus for transferring devices on one wafer to another wafer.

### BACKGROUND

Japanese Patent Application Laid-Open Publication No. 2024-062595 discloses a method for grinding one of two wafers in a bonded wafer, in which the two wafers are bonded together with a bonding film, and for transferring devices on the one wafer to the other wafer. The grinding process performed in this method may leave approximately 10 m of the one wafer to remain on the other wafer after grinding, thereby increasing a thickness of a stacked wafer where the devices are transferred. Moreover, the grinding process may often remove approximately 760 m of the one wafer, which increases the processing time. Meanwhile, Japanese Patent Application Laid-Open Publication No. 2021-006352 discloses a method for separating the one wafer by forming a separating layer inside a buffer layer with a laser beam. According to the latter publication, the grinding process required in the former publication may be omitted, and the processing time may be shortened.

### SUMMARY

However, according to the latter publication, even after being separated, a predetermined thickness of the one wafer is left on the devices that are transferred onto the other wafer. Therefore, a process such as polishing to flatten the surface of the other wafer from which the one wafer is separated, or etching to remove the one wafer remaining on the other wafer is required, and the productivity may be lowered.

The present disclosure has been made in view of these technical issues, and an objective is to provide a method for processing a bonded wafer and a processing apparatus which may improve productivity.

According to an aspect of the present disclosure, a method for processing a bonded wafer where a first wafer, in which a first device layer including first devices and an insulating film arranged in this order from a front surface side is formed on a front surface of a first substrate, and a second wafer are bonded, to transfer the first devices to the second wafer by separating at least the first substrate, includes a deforming step including deforming at least the first substrate such that a position on one side of the first substrate and a position on the other side of the first substrate in a planar direction are different in a direction intersecting with the planar direction, and a separating step including, after the deforming step, separating at least the first substrate leaving the first devices on the second wafer.

According to another aspect of the present disclosure, a processing apparatus configured to process a bonded wafer where a first wafer, in which a first device layer including first devices and an insulating film arranged in this order from a front surface side is formed on a front surface of a first substrate, and a second wafer are bonded, to transfer the first devices to the second wafer by separating the first substrate, includes a chuck table configured to hold the second wafer in the bonded wafer; a deforming unit configured to deform at least a part of the first substrate of the first wafer in the bonded wafer; and a separating unit configured to separate the deformed first substrate from the bonded wafer.

According to the present disclosure, the first substrate of the first wafer may be separated from the bonded wafer, a polishing process for making a flat surface after the separation may be omitted, and productivity may be improved.

### BRIEF DESCRIPTION OF THE DRAWINGS

FIGS. 1A-1C are explanatory views of a deforming step according to a first embodiment.

FIGS. 2A-2B are explanatory views of a separating step according to the first embodiment.

FIGS. 3A-3C are explanatory views of a deforming step according to a second embodiment.

FIGS. 4A-4B are explanatory views of a deforming step according to a third embodiment.

FIGS. 5A-5B are explanatory views of a deforming step according to a fourth embodiment.

FIGS. 6A-6B are explanatory views of a deforming step according to a fifth embodiment.

FIGS. 7A-7C are explanatory views of a deforming step according to a sixth embodiment.

FIG. 8A is an explanatory view of a surface-heating step according to a seventh embodiment, and FIGS. 8B-8C are explanatory views of a cooling step according to the seventh embodiment.

FIGS. 9A-9B are explanatory views of a deforming step according to an eighth embodiment.

FIG. 10A is an explanatory view of a lattice-defect layer forming step according to a ninth embodiment, and FIGS. 10B-10C are explanatory views of a deforming step according to the ninth embodiment.

FIG. 11 is an explanatory view of a deforming step according to a tenth embodiment.

FIGS. 12A-12C are explanatory views of a deforming step according to an eleventh embodiment.

FIGS. 13A-13C are explanatory views of a deforming step according to a twelfth embodiment.

FIGS. 14A-14B are explanatory views of a deforming step according to a thirteenth embodiment.

FIG. 15A is an explanatory view of a lattice-defect layer forming step according to a fourteenth embodiment, and FIGS. 15B-15C are explanatory views of a deforming step according to the fourteenth embodiment.

FIGS. 16A-16B are explanatory views of a separating step in a modified example.

### DESCRIPTION OF EMBODIMENTS

### First Embodiment

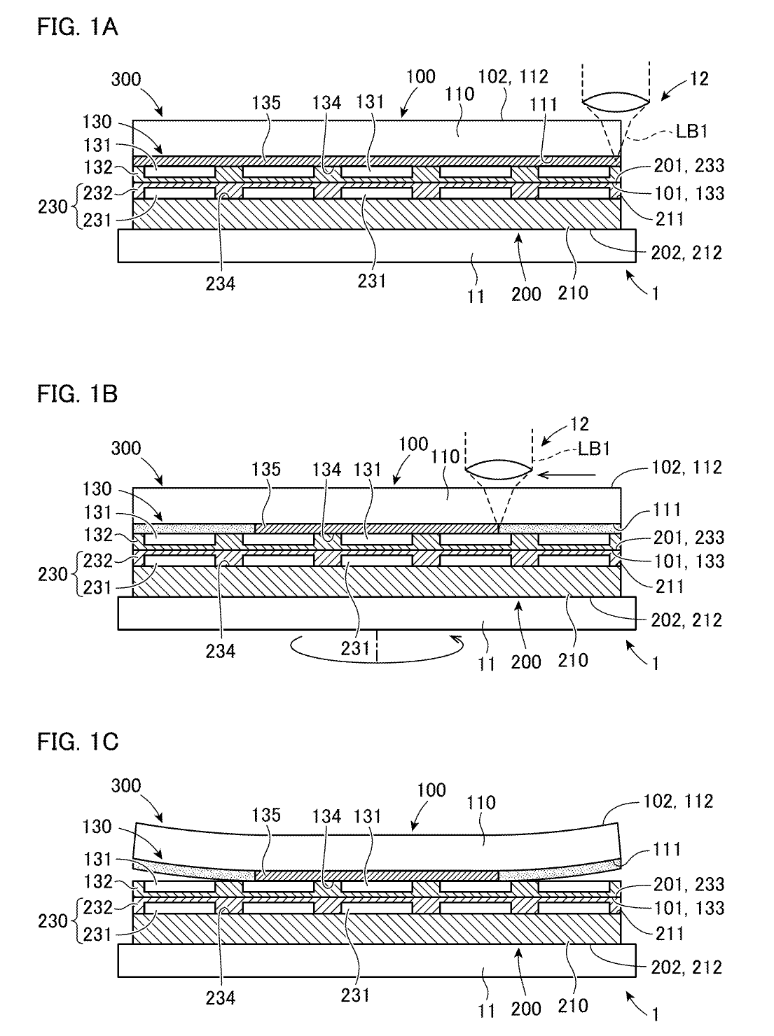

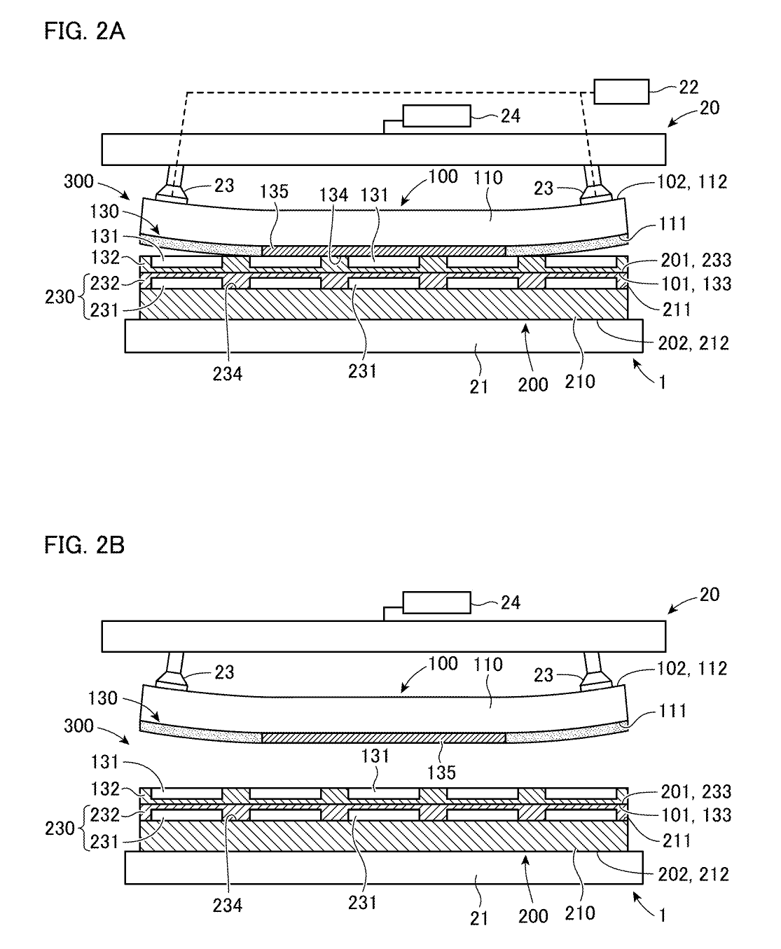

Hereinafter, a method for processing a bonded wafer according to a first embodiment will be described with reference to the accompanying drawings. FIGS. 1A-1C are explanatory views of a deforming step, and FIGS. 2A-2B are explanatory views of a separating step. Note steps shown in the drawings for the first embodiment are merely examples, and the present invention is not limited to these configurations. Further, in the drawings including FIG. 1A, note that hatching in a cross section of a first substrate 110, which will be described later, is omitted.

First, before describing these steps, a bonded wafer 300 to be processed in the processing method will be described with reference to FIG. 1A. The bonded wafer 300 is formed by bonding at least a first wafer 100 and a second wafer 200, which are each in a shape of a disk.

The first wafer 100 includes a front surface 101 and a back surface 102, which are surfaces spreading orthogonally to a thickness direction, and is arranged such that the front surface 101 faces downward and the back surface 102 faces upward in FIG. 1A. The second wafer 200 includes a front surface 201 and a back surface 202, which are surfaces spreading orthogonally to the thickness direction, and is arranged such that the front surface 201 faces upward and the back surface 202 faces downward in FIG. 1A.

The first wafer 100 includes a first substrate 110 made of silicon and a first device layer 130 formed on a front surface 111 side, which is one side in the thickness direction, of the first substrate 110. The back surface 102 of the first wafer 100 is formed of a back surface 112 of the first substrate 110.

The first device layer 130 includes a plurality of first devices 131, a first front-surface film 132 formed as a bonding film on surfaces of the plurality of first devices 131, and an insulating film 135. The front surface 101 of the first wafer 100 is formed of a front surface 133 of the first front-surface film 132 in the first device layer 130. Furthermore, the first device layer 130 includes the first front-surface film 132, the first devices 131, and the insulating film 135, which are arranged in this order from the front surface 133 toward the first substrate 110. In other words, the first wafer 100 is formed of the first front-surface film 132, the first devices 131, the insulating film 135, and the first substrate 110 arranged in this order from the front surface 101.

Each of the plurality of first devices 131 includes, for example, an element that forms an IC, a semiconductor memory, or an image sensor. The plurality of first devices 131 are formed in a plurality of regions respectively partitioned by a plurality of streets 134 in a grid formation. The first front-surface film 132 may be any of a silicon oxide film (SiO2 film), a silicon carbide film (SiC film), a silicon nitride film (SiN film), a silicon carbonitride film (SiCN film), a SiOC film, a SiON film, or a TEOS film.

The insulating film 135 is laminated between the first substrate 110 and the first devices 131, or in regions where the first devices 131 are not arranged, between the first substrate 110 and the first front-surface film 132, and is provided for formation of the first devices 131 on the front surface 111 side of the first substrate 110. Therefore, the first devices 131 are formed on a front surface (a lower surface in FIGS. 1A-1C) of the insulating film 135. The insulating film 135 may be any of, for example, a silicon oxide film (SiO2 film), a silicon carbide film (SiC film), a silicon nitride film (SiN film), a silicon carbonitride film (SiCN film), a SiOC film, a SiON film, or a TEOS film. The insulating film 135 absorbs a laser beam LB1 emitted thereon in the deforming step. Optionally, the insulating film 135 may not need to be newly formed as long as a film that absorbs the laser beam LB1 is provided. In other words, if a film of a silicon oxide film (SiO2 film), a silicon nitride film (SiN film), a silicon carbonitride film (SiCN film), or the like is formed when the first device layer 130 is produced, the film may be used as the insulating film 135 to absorb the laser beam LB1.

The second wafer 200 includes a second substrate 210 made of silicon similarly to the first substrate 110 described above, and a second device layer 230 formed on a front surface 211 side, which is one side in the thickness direction, of the second substrate 210. The back surface 202 of the second wafer 200 is formed of a back surface 212 of the second substrate 210.

The second device layer 230 is formed similarly to the first device layer 130, and includes a plurality of second devices 231 and a second front-surface film 232 formed as a bonding film on surfaces of the plurality of second devices 231. The front surface 201 of the second wafer 200 is formed of a front surface 233 of the second front-surface film 232 in the second device layer 230.As such, the second wafer 200 includes the second devices 231 on the front surface 201. Note that in the second wafer 200, similarly to the first wafer 100, an insulating film (not shown) is formed on the front surface 211 of the second substrate 210, and the second devices 231 are formed on a front surface of the insulating film.

Each of the plurality of second devices 231 also includes an element similar to the first devices 131, and is arranged so as to correspond to the first devices 131 by being formed in a plurality of regions partitioned by a plurality of streets 234 in a grid formation. The second front- surface film 232 is made of a material capable of bonding to the first front-surface film 132.

Before bonding the first and second wafers 100, 200 together, for example, the front surface 133 of the first front-surface film 132 of the first wafer 100 and the front surface 233 of the second front-surface film 232 of the second wafer 200 are each irradiated with a rare gas plasma generated using a rare gas and high-frequency power. Accordingly, the front surfaces 133, 233 of the first front-surface film 132 and the second front-surface film 232 are activated, and then the first and second wafers 100, 200 are bonded by plasma activation bonding on the front surfaces 133, 233. By this bonding, a bonded wafer 300 is formed, wherein the first devices 131 and the second devices 231 are bonded. Optionally, the second wafer 200 may be in a configuration that includes merely the second front-surface film 232 on the front surface 211 of the second substrate 210.

### Deforming Step

The bonded wafer 300 as above is processed in a deforming step as shown in FIGS. 1A- 1C. The deforming step is performed using a chuck table 11 and a laser emitter 12 that form the processing apparatus 1. In the deforming step, the bonded wafer 300 is held on the chuck table 11 by the side of the second wafer 200, and is conveyed by a conveyer, which is not shown. Thereafter, as shown in FIG. 1A, a laser beam LB1 having a wavelength that is transmissive through the first substrate 110 of the first wafer 100 is emitted in pulses from the back surface 102 side of the first wafer 100 from the laser emitter 12 onto the bonded wafer 300. In other words, the laser beam LB1 emitted from the laser emitter 12 irradiates the first wafer 100 from the first substrate 110 side (the back surface 102 side).

The laser beam LB1 used in the deforming step is set to have a wavelength X, which isin a range from 1000 nm to 3000 nm, inclusive, or 8000 nm to 11000 nm, inclusive. By setting the wavelength Kin this range, energy of the laser beam LB1 may be efficiently absorbed in the insulating film 135 at the focusing position while allowing the laser beam LB1 to transit through the first substrate 110 of the first wafer 100.

Emittance of the laser beam LB1 from the laser emitter 12 is adjusted such that the laser beam LB1 is focused on the insulating film 135 of the first wafer 100 through a focusing lens in the laser emitter 12. After this adjustment, the laser beam LB1 is emitted onto the insulating film 135 to form, for example, a spiral path centered on the center of the first wafer 100. While emitting, as shown in FIG. 1B, the chuck table 11 holding the bonded wafer 300 is rotated around an axis extending in a vertical direction, and the chuck table 11 and the laser emitter 12 are relatively moved in a horizontal direction.

By this relative movement, the irradiated position on the insulating film 135 with the laser beam LB1 shifts from an outer periphery, which is on one side in a planar direction of the first wafer 100, toward a center, which is on the other side in the planar direction of the first wafer 100. Thereafter, as the laser beam LB1 is emitted onto a region ranging from the outer periphery of the first wafer 100 to an intermediate position on the radius (indicated in dots in FIG. 1B), the emittance of the laser beam LB1 is stopped. Accordingly, a circular region, of which outer circumference is at approximately half of the radius from the center of the first wafer 100, is left unirradiated with the laser beam LB1, but in a region in a ring (annular) shape outside the circular region, the insulating film 135 is irradiated with the laser beam LB1.

In the region in the insulating film 135 irradiated with the laser beam LB1, lattice defects are increased by heat while a single crystal structure is maintained. Moreover, when an output of the laser beam LB1 is increased, the insulating film 135 is reformed from the single crystal structure to a polycrystal structure. When the insulating film 135 is reformed into the polycrystal structure by the heat, a volume of the insulating film 135 thermally expands, and the first substrate 110 is deformed by the thermally expanded insulating film 135 as shown in FIG. 1C. Accordingly, the insulating film 135 separates from the first devices 131 and the first front- surface film 132 in the first device layer 130 within the ring-shaped region along the outer periphery, i.e., an outer peripheral portion, of the first substrate 110, and the first substrate 110 deforms into an upward warped shape together with the insulating film 135. In other words, the first substrate 110 is deformed such that a position thereof on the outer periphery, i.e., on one side in the planar direction (horizontal direction), and a position thereof at the center, i.e., on the other side in the planar direction, are different in a direction intersecting with the planar direction of the first substrate 110, i.e., the vertical direction in FIG. 1C. That is, the first device layer 130 is distorted at an interface between the first devices 131 and the insulating film 135 and between the first front-surface film 132 and the insulating film 135, causing the first substrate 110 to easily separate from the first devices 131 and the first front-surface film 132.

Optionally, the laser emitter 12 may be a laser unit that emits the laser beam LB1 onto the first wafer 100 to heat the first substrate 110. In other words, the laser unit may be a temperature-difference creating unit that may heat the first wafer 100 by emittance of the laser beam LB1 to create a temperature difference between the first wafer 100 and the second wafer 200. Note that the laser beam from the laser emitter 12 that irradiates the first wafer 100 may be modified, as described later. Furthermore, the laser emitter 12 is a deforming device that may deform at least a part of the first substrate 110 in the first wafer 100 of the bonded wafer 300. Optionally, the temperature-difference creating unit to create a temperature difference between the first wafer 100 and the second wafer 200 may be a cooling unit that cools the first wafer 100 or the second wafer 200, as described later.

### Separating Step

After the deforming step, a separating step to separate the first substrate 110 of the first wafer 100 from the second wafer 200 is performed, as shown in FIG. 2A and 2B. The separating step is performed using a separating apparatus 20 (separating unit) that forms the processing apparatus 1. In the separating step, the bonded wafer 300 is conveyed to and held by a chuck table 21 in the separating apparatus 20 (see FIG. 2A) via a conveyer (not shown). Next, the back surface 102 of the first wafer 100 in the bonded wafer 300 is held by suction pads 23, which are connected to a suction source 22 and generate a negative pressure at each lower end. According to the present embodiment, the back surface 102 of the first wafer 100 is held by the suction pads 23 at a plurality of locations toward the outer periphery of the back surface 102.

Thereafter, as shown in FIG. 2B, the suction pads 23 are lifted upward via a lift/lower mechanism 24, and a force to separate the first wafer 100 from the second wafer 200 is applied to the first substrate 110. Accordingly, a lower surface (front surface) of the insulating film 135 in FIG. 2B is separated from upper surfaces (back surfaces) of the first devices 131 and the first front-surface film 132 in the first device layer 130, and the first substrate 110 and the insulating film 135 in the first device layer 130 are separated from the bonded wafer 300. As such, in the first wafer, where the insulating film 135 such as thermal oxide film or a thermal nitride film is formed on the first substrate 110 by thermal processing, bond between the first substrate 110 and the insulating film 135 is strong; therefore, the insulating film 135 is separated together with the first substrate 110. After the separation, the first devices 131 remain bonded to the second wafer 200. Therefore, by performing the separating step, the first devices 131 are transferred (left) to the second wafer 200, and the bonded wafer 300 where transfer is completed is formed.

According to the first embodiment described above, the first substrate 110 may beseparated together with the insulating film 135 at the interface between the first devices 131 and the insulating film 135 and between the first front-surface film 132 and the insulating film 135 in the first device layer 130. Optionally, in a case where the insulating film 135 is formed using plasma CVD, the bonding strength between the insulating film 135 and the first substrate 110 is not strong; therefore, solely the first substrate 110 may be separated at the interface between the insulating film 135 and the first substrate 110. Accordingly, a polishing process for making an upper surface of the bonded wafer 300, as in FIG. 1C, which is exposed after the separation of the first substrate 110, into a flat surface may be omitted, and productivity may be improved.

Next, other embodiments of the present disclosure than the above will be described. In the following description, the same reference numerals may be used for components that are the same as or equivalent to those in the embodiment described earlier, and description of those may be omitted or simplified.

### Second Embodiment

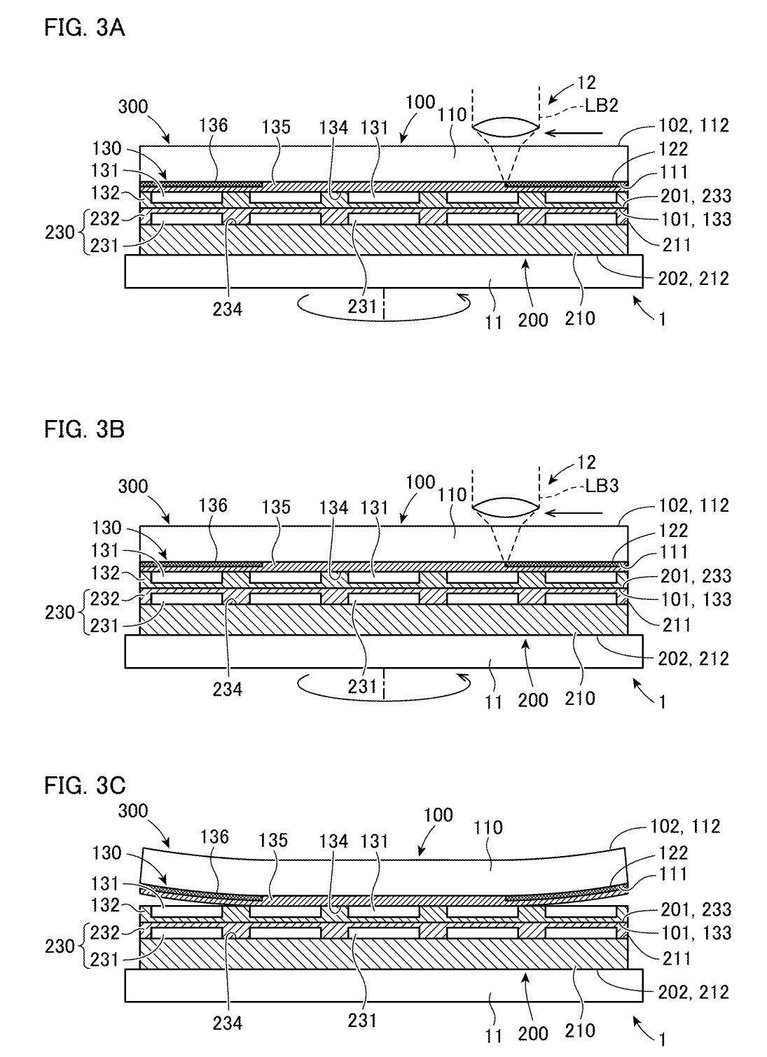

Next, a second embodiment of the present disclosure will be described with reference to FIGS. 3A-3C. FIGS. 3A-3C are explanatory views of a deforming step in the method for processing a bonded wafer according to the second embodiment. In the second embodiment, the deforming step is modified from that of the first embodiment.

### Deforming Step

In the deforming step of the second embodiment, as shown in FIG. 3A, a laser beam LB2 having a wavelength that is transmissive through the insulating film 135 is emitted in pulses from the laser emitter 12 onto the back surface 102 of the first wafer 100. A wavelength X of the laser beam LB2 is within a range of 1000 nm to 3000 nm, inclusive, or 8000 nm to 11000 nm, inclusive, and is lower in output than the laser beam LB1 emitted in the deforming step of the first embodiment. The laser beam LB2 in the second embodiment may have the same wavelength as the laser beam LB1 in the first embodiment.

In the second embodiment, the laser beam LB2 is emitted onto the insulating film 135 in a manner similar to the laser beam LB1 of the first embodiment, in such a way that the laser beam LB2 forms a spiral path centered on the center of the first wafer 100. Furthermore, the laser beam LB2 is emitted onto the insulating film 135 in a region ranging from the outer periphery of the first wafer 100 to an intermediate position on the radius, forming a ring-shaped lattice-defect layer 136 within the insulating film 135 as shown in FIG. 3A. When viewed from above, the lattice-defect layer 136 is formed in an annular region along the outer periphery of the first wafer 100 (insulating film 135).

In the deforming step of the second embodiment, the lattice-defect layer 136 is further irradiated with a pulsed laser beam LB3 having a wavelength that is transmissive through the insulating film 135 emitted from the laser emitter 12. The laser beam LB3 also has the wavelength X in the range of 1000 nm to 3000 nm, inclusive, or 8000 nm to 11000 nm, inclusive, and has a lower output than the laser beam LB2. The laser beam LB3 may have either the same wavelength as the laser beam LB2 or the same wavelength as the laser beam LB1 in the first embodiment. The laser beam LB3 is emitted onto a region in a ring (annular) shape along the outer periphery of the insulating film 135, i.e., the region where the lattice-defect layer 136 is formed, similarly to the laser beam LB2.

Accordingly, the lattice-defect layer 136 is heated, and the first substrate 110 is deformed by the heat as shown in FIG. 3C. This deformation is similar to that in the first embodiment, with the insulating film 135 separating from the first devices 131 and first front- surface film 132 in the first device layer 130, and deforming the first substrate 110 into an upward warped shape together with the insulating film 135.

According the second embodiment as well, the first substrate 110 may be deformed similarly to the first embodiment, and the first substrate 110 may be separated using the lattice- defect layer 136 formed in the insulating film 135 as a separation-starting point by performing the separating step.

### Third Embodiment

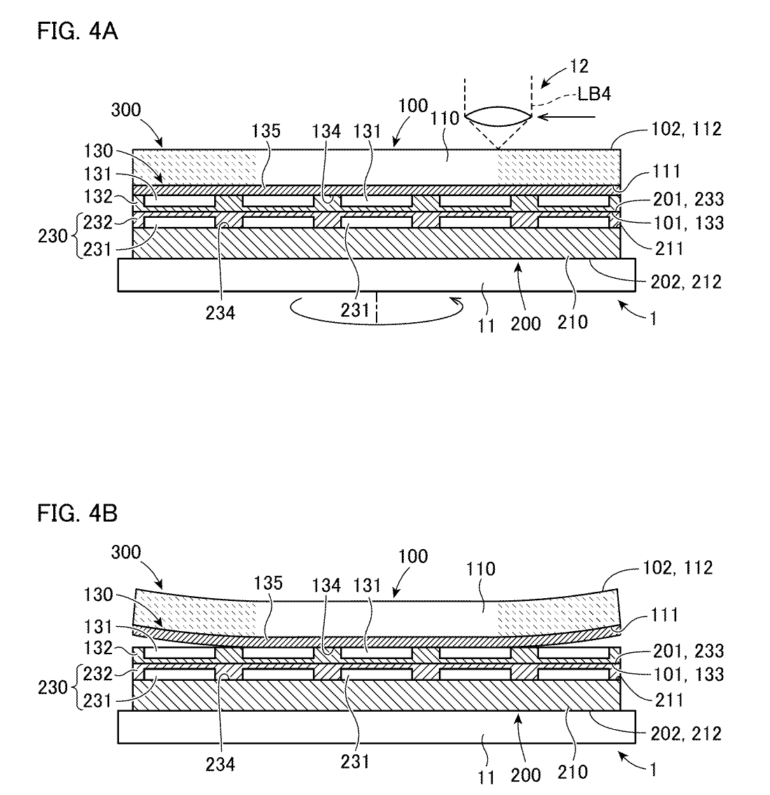

Next, a third embodiment of the present disclosure will be described with reference to FIGS. 4A-4B. FIGS. 4A-4B are explanatory views of a deforming step in the method for processing a bonded wafer according to the third embodiment. In the third embodiment, the deforming step is modified from that of the first embodiment.

### Deforming Step

In the deforming step of the third embodiment, as shown in FIG. 4A, a laser beam LB4 having an absorption wavelength X of, for example, 455 nm is emitted from the laser emitter12 onto the back surface 112 of the first substrate 110 of the first wafer 100. In the third embodiment, the laser beam LB4 is emitted in a manner similar to the laser beam LB1 of the first embodiment, in such a way that the laser beam LB4 forms a spiral path centered on the center of the first wafer 100. Accordingly, the first substrate 110 is irradiated with the laser beam LB4 throughout a region ranging from the outer periphery of the first wafer 100 to an intermediate position on the radius, as indicated in a broken diagonal-line pattern in FIG. 4A, and the first substrate 110 is heated in a range of a ring (annular) shape. The range is an annular region along the outer periphery of the first wafer 100 in a view from above.

By this heat, the first substrate 110 is thermally deformed as shown in FIG. 4B. This thermal deformation is similar to that in the first embodiment, where the insulating film 135 separates from the first devices 131 and the first front-surface film 132 in the first device layer130, and the first substrate 110 deforms into an upward warped shape together with the insulating film 135.

According to the third embodiment as well, the first substrate 110 may be deformed similarly to the first embodiment. Accordingly, by performing the separating step, the first substrate 110 may be separated together with the insulating film 135 at the interface between the first devices 131 and the insulating film 135 and between the first front-surface film 132 and the insulating film 135 in the first device layer 130, or the first substrate 110 alone may be separated at the interface between the insulating film 135 and the first substrate 110. Optionally, the first wafer 100 may be heated by a heater unit that blows, for example, warm air or hot air onto the first wafer 100.

### Fourth Embodiment

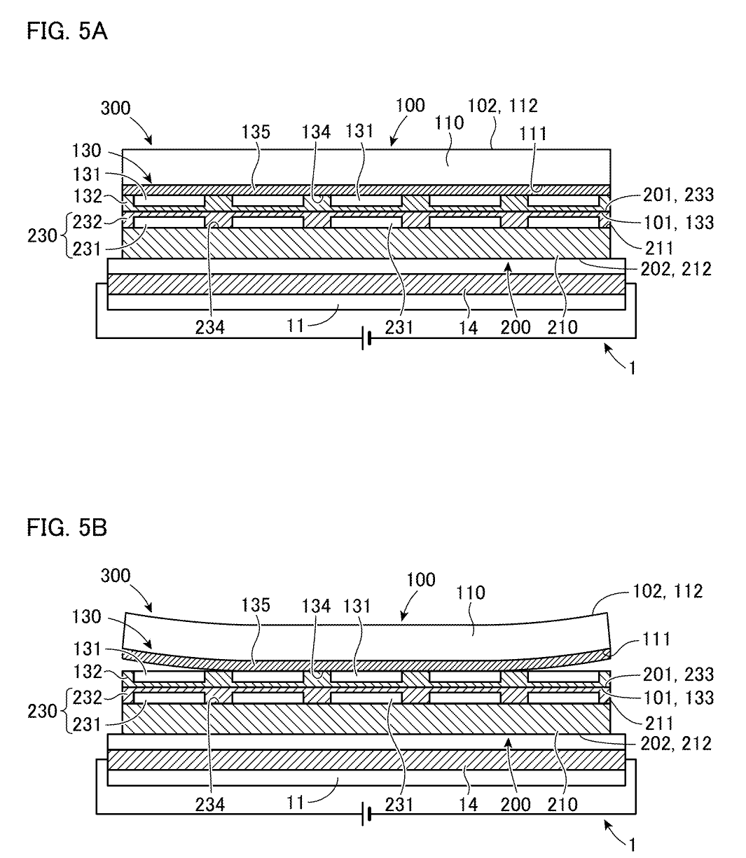

Next, a fourth embodiment of the present disclosure will be described with reference to FIGS. 5A-5B. FIGS. 5A-5B are explanatory views of a deforming step in the method for processing a bonded wafer according to the fourth embodiment. In the fourth embodiment, the deforming step is modified from that of the first embodiment.

The deforming step of the fourth embodiment uses a chuck table 11, as shown in FIG. 5A, in which a Peltier device 14 is arranged, and the second substrate 210 (second wafer 200) of the bonded wafer 300 held on the chuck table 11 is cooled by the Peltier device 14. By this cooling effect, the first substrate 110 is thermally deformed as shown in FIG. 5B . This thermal deformation is equated as the first embodiment, where the insulating film 135 separates from the first devices 131 and the first front-surface film 132 in the first device layer 130, and the first substrate 110 deforms into an upward warped shape together with the insulating film 135.

In this regard, the Peltier device 14 is a cooling unit that cools the second wafer 200, and is a temperature-difference creating unit that cools the second wafer 200 to create a temperature difference between the first wafer 100 and the second wafer 200. Furthermore, the Peltier device 14 is a deforming unit that deforms at least a part of the first substrate 110 in the first wafer 100 of the bonded wafer 300.

According to the fourth embodiment as well, the first substrate 110 may be deformed similarly to the first embodiment, and the first substrate 110 may be separated at the interface between the first devices 131 and the insulating film 135 and between the first front-surface film 132 and the insulating film 135 in the first device layer 130 by performing the separating step. Optionally, the bonded wafer 300 may be warmed before cooled by the cooling unit. Optionally, the second substrate 210 may be cooled through the chuck table 11 by circulating a coolant within the chuck table 11, or by blowing cold air onto the second substrate.

Optionally, the second substrate 210 may be cooled through the chuck table 11 by circulating a coolant within the chuck table 11, or by blowing cold air onto the second substrate210 while the bonded wafer 300 is clamped at a peripheral edge. Furthermore, for another example, the second substrate 210 may be cooled by bringing a cooled member other than the chuck table 11 into contact with the second substrate 210, or by irradiating the second substrate 210 with a laser. For another example, moreover, the second substrate 210 may be cooled by injecting cold gas (liquid nitrogen) there-onto from a nozzle.

### Fifth Embodiment

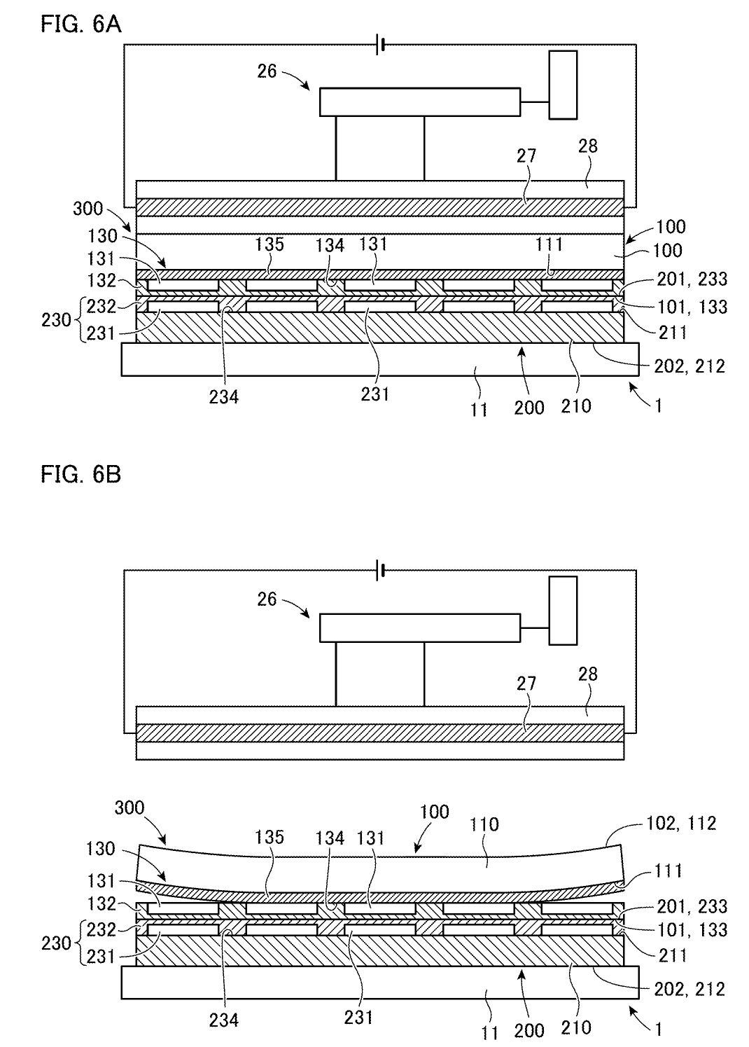

Next, a fifth embodiment of the present disclosure will be described with reference to FIGS. 6A-6B. FIGS. 6A-6B are explanatory views of a deforming step in the method for processing a bonded wafer according to the fifth embodiment. In the fifth embodiment, the deforming step is modified from that of the first embodiment.

The deforming step of the fifth embodiment uses, as shown in FIGS. 6A-6B, a conveyer 26 including a conveyer pad 28, in which a Peltier device 27 is disposed, and the first substrate 110 (first wafer 100) of the bonded wafer 300 held on the conveyer pad 28 is cooled by the Peltier device 27. Due to this cooling effect, the first substrate 110 is thermally deformed as shown in FIG. 6B. This thermal deformation is equated as the first embodiment, where the insulating film 135 separates from the first devices 131 and the first front-surface film 132 in the first device layer 130, and the first substrate 110 deforms into an upward warped shape together with the insulating film 135.

In this regard, the Peltier device 27 is a cooling unit that cools the first wafer 100, and is a temperature-difference creating unit that cools the first wafer 100 to create a temperature difference between the first wafer 100 and the second wafer 200. Furthermore, the Peltier device 27 is a deforming device that deforms at least a part of the first substrate 110 in the first wafer 100 of the bonded wafer 300.

According to the fifth embodiment as well, the first substrate 110 may be deformed similarly to the first embodiment, and the first substrate 110 may be separated at the interface between the first devices 131 and the insulating film 135 and between the first front-surface film 132 and the insulating film 135 in the first device layer 130 by performing the separating step. Optionally, the bonded wafer 300 may be warmed before cooled by the cooling unit. Furthermore, optionally, the first substrate 110 may be cooled by injecting cold gas (liquid nitrogen) there-onto from a nozzle, or may be cooled with laser. [Sixth Embodiment]

Furthermore, optionally, the first substrate 110 may be cooled by injecting cold gas (liquid nitrogen) there-onto from a nozzle, or may be cooled with laser.

### Sixth Embodiment

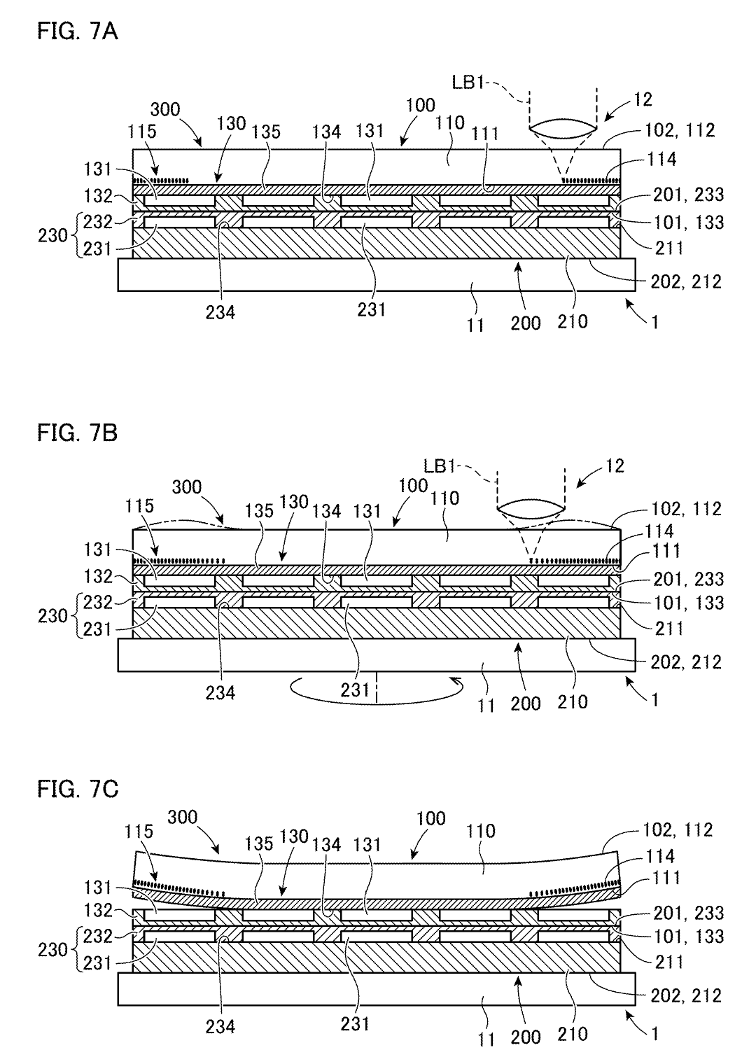

Next, a sixth embodiment of the present disclosure will be described with reference to FIGS. 7A-7C. FIGS. 7A-7C are explanatory views of a deforming step in the method for processing a bonded wafer according to the sixth embodiment. In the sixth embodiment, the focusing position of the laser beam LB1 in the deforming step is modified from that of the first embodiment. The laser beam LB1 to be emitted in the deforming step has a wavelength transmissive through the first substrate 110, similarly to the first embodiment.

As shown in FIG. 7A, in the deforming step of the sixth embodiment, emittance of the laser beam LB1 is adjusted such that the laser beam LB1 is focused at a position inside the first substrate 110 of the first wafer 100 through the focusing lens in the laser emitter 12. More specifically, the focusing position of the laser beam LB1 in the bonded wafer 300 is a position shifted from the front surface 111 toward the back surface 112 but in proximity to the front surface 111 of the first substrate 110.

After adjusting the focusing position of the laser beam LB1, the laser beam LB1 is emitted onto the first substrate 110 to form a spiral path centered on the center of the first wafer 100 in a view along the vertical direction (the thickness direction of the first wafer 100) in, for example, FIG. 7A. While emitting, as shown in FIG. 7B, the chuck table 11 holding the bonded wafer 300 and the laser emitter 12 are relatively moved in the horizontal direction while the chuck table 11 is being rotated around the axis extending in the vertical direction.

By this relative movement, the irradiation position on the first substrate 110 with the laser beam LB1 shifts from the outer periphery of the first substrate 110 toward the center along the spiral path, and a plurality of processed marks 114 are formed at predetermined intervals along the path. The processed marks 114 are formed so as to reform the interior of the first substrate 110 from the single crystal to a polycrystal. After the laser beam LB1 is emitted onto a region ranging from the outer periphery of the first substrate 110 to an intermediate position on the radius, the emittance of the laser beam LB1 is stopped.

Accordingly, the plurality of processed marks 114 form a modified layer 115 in the first substrate 110 in an annular region along the outer peripheral side (one side in a planar direction) of the first substrate 110. Due to the formation of the modified layer 115, a volume of a portion of the first substrate 110 in proximity to the bonding surface with the first device layer 130 expands, as indicated in dash-and-dots lines in FIG. 7B. According to this expansion, as shown in FIG. 7C, similarly to the first embodiment, the insulating film 135 separates from the first devices 131 and the first front-surface film 132 in the first device layer 130 in the region in the ring (annular) shape along the outer periphery of the first substrate 110, and the first substrate 110 deforms into an upward warped shape together with the insulating film 135.

According to the sixth embodiment as well, the first substrate 110 may be deformed similarly to the first embodiment, and the first substrate 110 may be separated at the interface between the first devices 131 and the insulating film 135 and between the first front-surface film 132 and the insulating film 135 in the first device layer 130 by performing the separating step.

Note that, as shown in FIGS. 7A-7C, in a radial direction of the first substrate 110, theinterval of the processed marks 114 in the modified layer 115 is set so as to gradually increase from the outer periphery toward the center, and by setting to such an interval, the warp of the first substrate 110 may be stably formed. However, this does not prevent the interval between the processed marks 114 from being set to constant throughout the radial direction of the first substrate 110.

### Seventh Embodiment

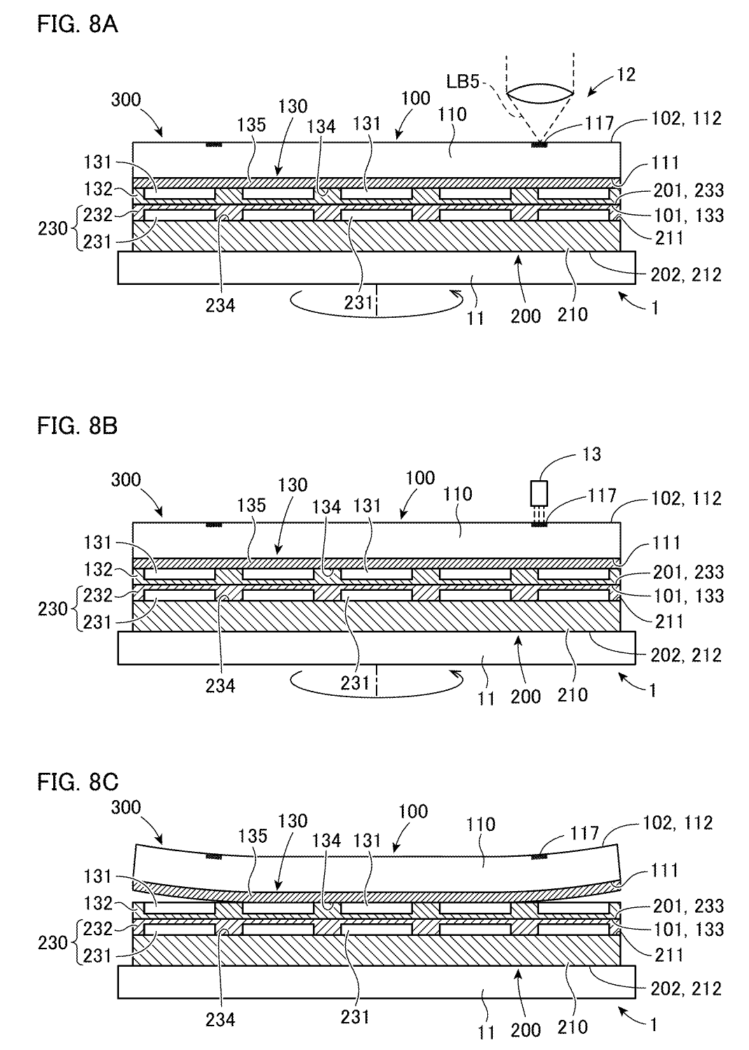

Next, a seventh embodiment of the present disclosure will be described with reference to FIGS. 8A-8C. FIGS. 8A-8C are explanatory views of steps in the method for processing a bonded wafer according to the seventh embodiment: FIG. 8A is an explanatory view of a surface-heating step, and FIGS. 8B-8C are explanatory views of a cooling step. In the seventh embodiment, the deforming step is modified from that of the first embodiment. In the deforming step of the seventh embodiment, the surface-heating step and the cooling step are performed sequentially for laser forming.

### Surface-Heating Step

In the surface-heating step, the back surface 202 of the second wafer 200 in the bonded wafer 300 is held to face downward on the chuck table 11 of the processing apparatus 1, and thereafter, the laser emitter 12 is faced toward the back surface 102 of the first wafer 100. Further, the laser emitter 12 and the chuck table 11 are relatively moved, and the laser emitter 12 is located above an intermediate position on the radius of the first wafer 100. Thereafter, a laser beam LBS having an absorptive wavelength (for example, 455 nm) is emitted in pulses onto the first substrate 110 of the first wafer 100.

In the surface-heating step, emittance of the laser beam LBS is adjusted such that the laser beam LBS is focused on the back surface 112 of the first substrate 110 through the focusing lens in the laser emitter 12. After this adjustment, the laser beam LBS is emitted from the laser emitter 12 while the chuck table 11 holding the bonded wafer 300 is rotated around the axis extending in the vertical direction. Accordingly, the laser beam LBS is emitted onto the back surface 112 of the first substrate 110 so as to form a circular path centered on the center of the back surface 112 of the first substrate 110, and the first substrate 110 is heated at the irradiated position.

### Cooling Step

After the surface-heating step, the cooling step is performed for cooling a portion 117 of the first substrate 110 that was heated in the surface-heating step, as shown in FIG. 8B. In the cooling step, the chuck table 11 holding the bonded wafer 300 and a cooling fluid supply device 13 are relatively moved, and the cooling fluid supply device 13 is located above the heated portion 117 of the first substrate 110. Thereafter, air as a cooling fluid is blown from the cooling fluid supply device 13 while the chuck table 11 is rotated around the axis extending in the vertical direction. Accordingly, the heated portion 117 on the back surface 112 of the first substrate 110 is cooled and locally contracts. Due to this contraction, as shown in FIG. 8C, on a side toward the outer periphery with respect to the heated portion 117, the insulating film 135 separates from the first devices 131 and the first front-surface film 132 in the first device layer 130, and the first substrate 110 deforms into an upward warped shape together with the insulating film 135.

In the seventh embodiment, the first substrate 110 may be bent due to the local thermoplastic deformation caused by the laser forming performed in the surface-heating step and the cooling step. According to the seventh embodiment as well, the first substrate 110 may be deformed similarly to the first embodiment, and the first substrate 110 may be separated at the interface between the first devices 131 and the insulating film 135 and between the first front- surface film 132 and the insulating film 135 in the first device layer 130 by performing the separating step. Optionally, in the cooling step, as long as the portion of the first substrate 110 heated in the surface-heating step is cooled, air for cooling may be blown over the entire back surface 112 of the first substrate 110. Furthermore, optionally, blowing of the air may be omitted, while merely the chuck table 11 is rotated.

### Eighth Embodiment

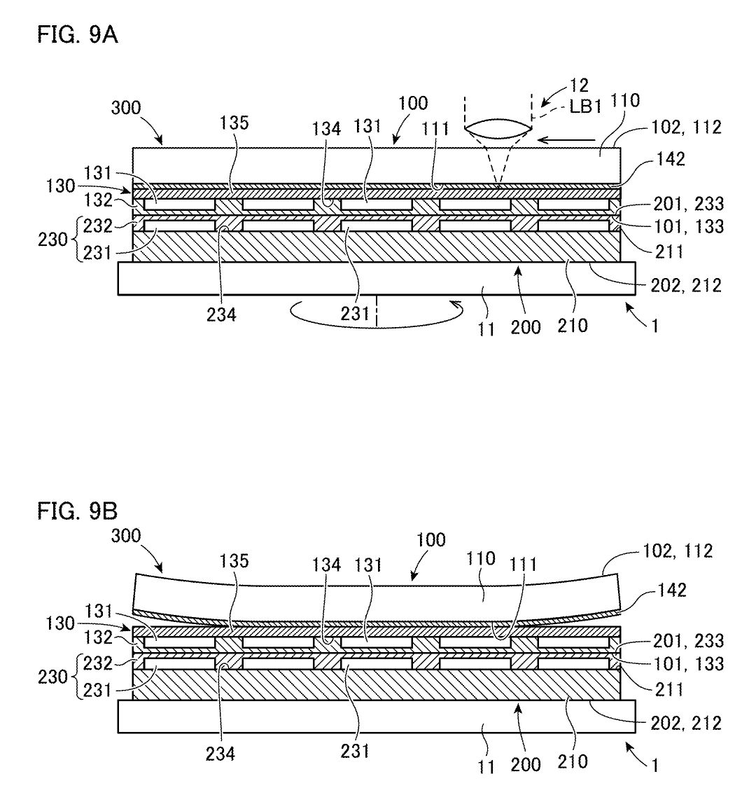

Next, an eighth embodiment of the present disclosure will be described with reference to FIGS. 9A-9B. FIGS. 9A-9B are explanatory views of a deforming step in the method for processing a bonded wafer according to the eighth embodiment. In the eighth embodiment, the configuration of the first wafer 100 is modified from that of the first embodiment. Furthermore, in the eighth embodiment, the irradiation position with the laser beam LB1 in the deforming step and the separating position of the first substrate 110 are modified from those of the first embodiment.

The first wafer 100 in the eighth embodiment includes, as shown in FIG. 9A, a metal film 142 between the front surface 111 of the first substrate 110 and the insulating film 135 of the first device layer 130. The metal film 142 may be formed by vapor deposition or sputtering using materials such as polysilicon, titanium, nickel, Si-Ge, and SiN. The bonding strength between the metal film 142 and the insulating film 135 is less than the bonding strength between the metal film 142 and the first substrate 110.

In the deforming step of the eighth embodiment, the laser emitter 12 emits the laser beam LB1 having the same wavelength K and output as those in the first embodiment onto the metal film 142, thereby heating the metal film 142. The laser beam LB1 is emitted onto the metal film 142 so as to form a spiral path centered on the center of the first wafer 100. Furthermore, the laser beam LB1 is emitted onto the metal film 142 throughout a region ranging from the outer periphery of the first wafer 100 to an intermediate position on the radius, and the metal film 142 is irradiated with the laser beam LB1 throughout a region in a ring (annular) shape along the outer periphery thereof. Due to the heat generated in the metal film 142, the metal film 142 and the insulating film 135, which have the less bonding strength, are separated as shown in FIG. 9B, and the first substrate 110 deforms into an upward warped shape together with the metal film 142.

According to the eighth embodiment as well, the first substrate 110 may be deformed similarly to the first embodiment, and the first substrate 110 may be separated at the interface between the insulating film 135 and the metal film 142 by performing the separating step. When separating, unlike the first embodiment, the first substrate 110 separates from the insulating film 135, and the insulating film 135 remains bonded to the first devices 131 and the first front- surface film 132 in the first device layer 130.

### Ninth Embodiment

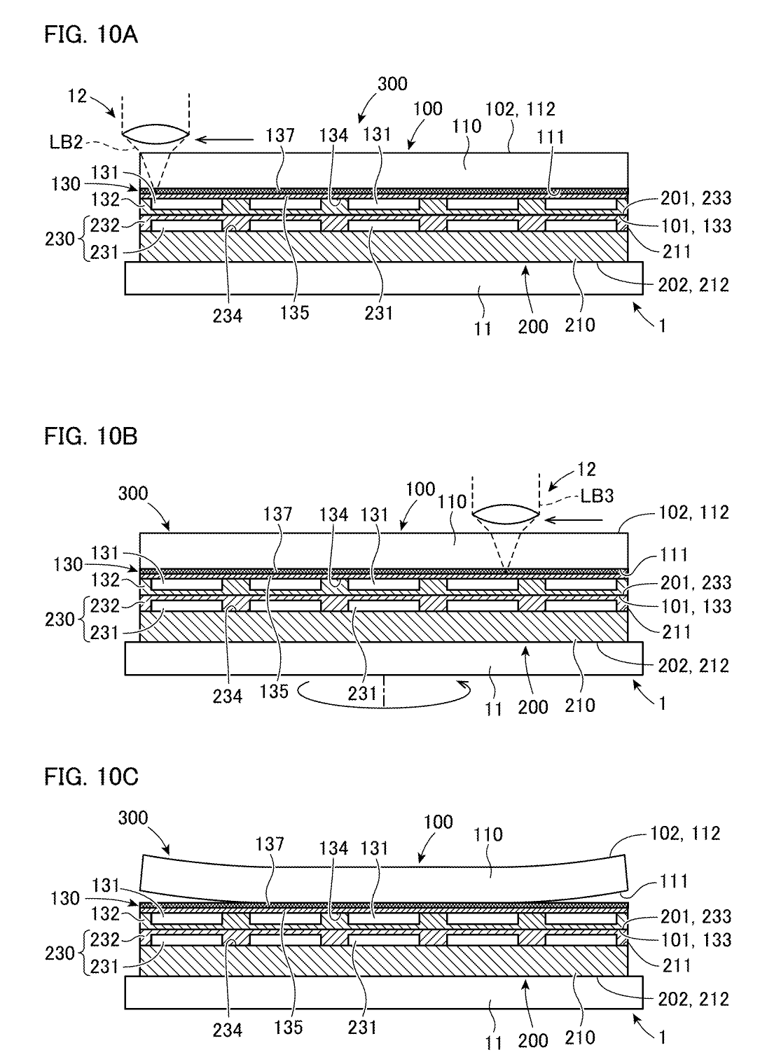

Next, a ninth embodiment of the present disclosure will be described with reference to FIGS. 10A-10C. FIGS. 10A-10C are explanatory views of steps in the method for processing a bonded wafer according to the ninth embodiment: FIG. 10A is an explanatory view of a lattice- defect layer forming step, and FIGS. lOB-lOC are explanatory views of a deforming step. The ninth embodiment is mainly different from the first embodiment in that a lattice-defect layer forming step is performed prior to the deforming step.

### Lattice-Defect Layer Forming Step

In the lattice-defect layer forming step, a lattice-defect layer 137, which has a similar structure to the lattice-defect layer 136 of the second embodiment but has a different formation range, is formed within the insulating film 135 of the first device layer 130.

In the lattice-defect layer forming step, the laser emitter 12 emits a laser beam LB2 having the same wavelength X and output as those in the second embodiment onto the insulating film 135. The laser beam LB2 is emitted onto the insulating film 135 so as to form a spiral path centered on the center of the first wafer 100. Furthermore, the laser beam LB2 is emitted over substantially the entire range of the insulating film 135 extending from the outer periphery to the center of the first wafer 100. Therefore, as shown in FIG. 10A, a planar lattice-defect layer 137 is formed within the insulating film 135; in other words, substantially the entire area of the surface of the insulating film 135 on the upper side in FIG. 10A (back surface side) is modified into the lattice-defect layer 137.

### Deforming Step

In the deforming step of the ninth embodiment, as shown in FIG. lOB, the laser emitter 12 emits a laser beam LB3 having the same wavelength K and output as those in the second embodiment onto the insulating film 135. The laser beam LB3 is emitted onto the insulating film 135 so as to also form a spiral path centered on the center of the first wafer 100. Furthermore, the laser beam LB3 is emitted onto the insulating film 135 throughout a region ranging from the outer periphery of the first wafer 100 to an intermediate position on the radius, and the insulating film 135 is irradiated with the laser beam LB3 throughout a region in a ring (annular) shape along the outer periphery thereof. Accordingly, the insulating film 135 is heated, and by this heat, the first substrate 110 is deformed as shown in FIG. 10C. Due to this deformation, the first substrate 110 separates from the lattice-defect layer 137 of the insulating film 135, and the first substrate 110 is deformed into an upward warped shape.

According to the ninth embodiment as well, the first substrate 110 may be deformed similarly to the first embodiment, and by performing the separating step, the first substrate 110 alone may be separated at the interface between the lattice-defect layer 137 of the insulating film 135 and the first substrate 110. When separating, the first substrate 110 separates from the insulating film 135, and the insulating film 135 remains bonded to the first devices 131 and the first front-surface film 132 in the first device layer 130.

### Tenth Embodiment

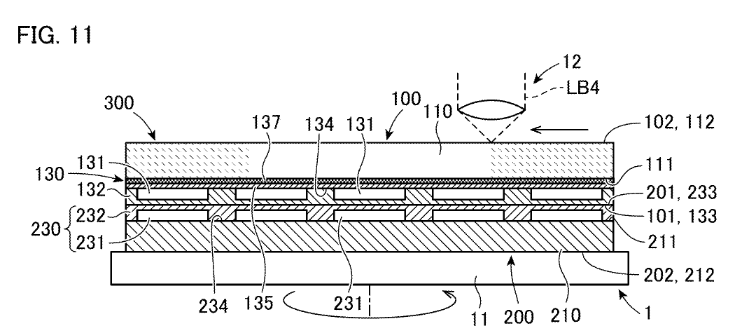

Next, a tenth embodiment of the present disclosure will be described with reference to FIG. 11. FIG. 11 is an explanatory view of a deforming step in the method for processing a bonded wafer according to the tenth embodiment. In the tenth embodiment, the deforming step is modified from that of the ninth embodiment.

### Deforming Step

In the deforming step of the tenth embodiment, as shown in FIG. 11, the laser emitter 12 emits a laser beam LB4 having the same wavelength K and output as those in the third embodiment onto the back surface 112 of the first substrate 110 in the first wafer 100. The laser beam LB4 is emitted onto the first substrate 110 so as to also form a spiral path centered on the center of the first wafer 100, similarly to the laser beam LB4 of the third embodiment. Accordingly, the first substrate 110 is irradiated with the laser beam LB4 throughout a region in a ring (annular) shape ranging from the outer periphery of the first wafer 100 to an intermediate position on the radius, as indicated in a broken diagonal-line pattern in FIG. 11, and the first substrate 110 is heated.

By this heat, the first substrate 110 is deformed similarly to the ninth embodiment, and the first substrate 110 separates at the lattice-defect layer 137 in the insulating film 135, resulting in the first substrate 110 to deform into an upward warped shape (see FIG. 10C). Accordingly, in the tenth embodiment as well, similarly to the ninth embodiment, the first substrate 110 may be separated at the interface between the lattice-defect layer 137 in the insulating film 135 and the first substrate 110 by performing the separating step.

Optionally, in a case where the planar lattice-defect layer 137 is formed within the insulating film 135, the deforming step is not limited to that in the ninth or tenth embodiment, but a modified layer 115 may be formed within the first substrate 110 similarly to the sixth embodiment, or laser forming may be performed similarly to the seventh embodiment.

### Eleventh Embodiment

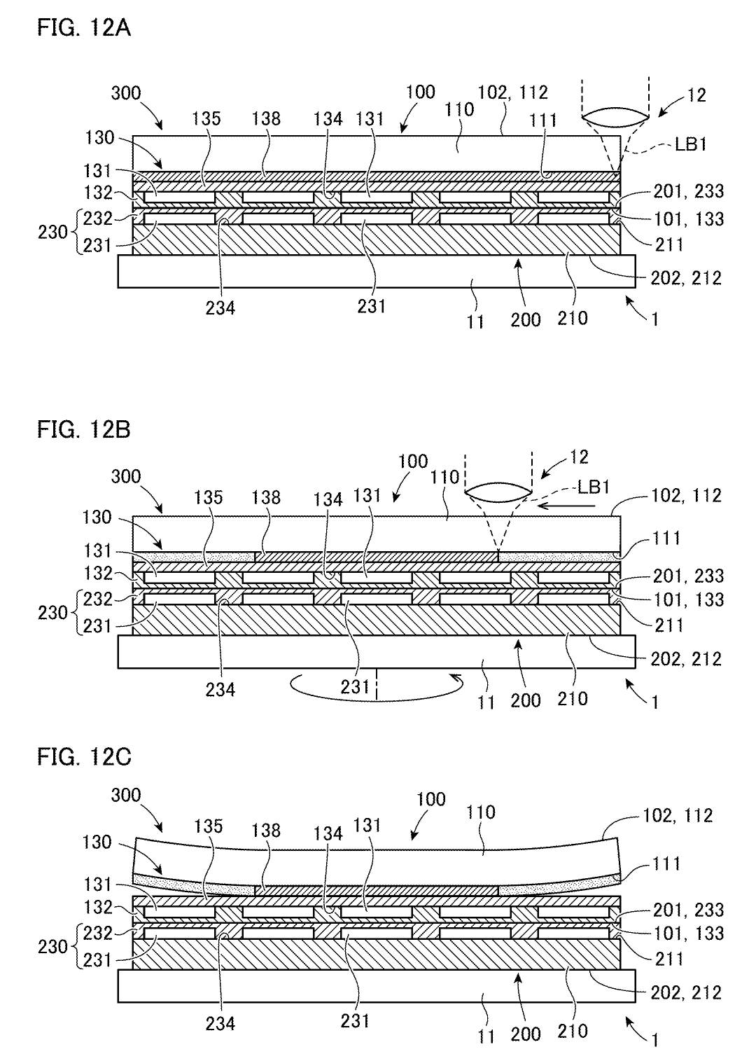

Next, an eleventh embodiment of the present disclosure will be described with reference to FIGS. 12A-12C. FIGS. 12A-12C are explanatory views of a deforming step in the method for processing a bonded wafer according to the eleventh embodiment. In the eleventh embodiment, the configuration of the first wafer 100 is modified from that of the first embodiment.

Furthermore, in the eleventh embodiment, the irradiation position with the laser beam LB 1 in the deforming step and the separating position of the first substrate 110 are modified from those of the first embodiment.

The first device layer 130 of the first wafer 100 in the eleventh embodiment includes a separation-promoting film 138 laminated between the first substrate 110 and the insulating film 135, as shown in FIG. 12A. As such, the first device layer 130 includes the first devices 131, the insulating film 135, and the separation-promoting film 138 arranged in this order from the front surface 133. The separation-promoting film 138 may be formed of the same material as the insulating film 135, and the bonding strength between the separation-promoting film 138 and the insulating film 135 is less than the bonding strength between the separation-promoting film 138 and the first substrate 110.

In the deforming step of the eleventh embodiment, as shown in FIG. 12B, the laser emitter 12 emits the laser beam LB1 having the same wavelength K and output as those in the first embodiment onto the separation-promoting film 138, thereby heating the separation- promoting film 138. The laser beam LB1 is emitted onto the separation-promoting film 138 so as to form a spiral path centered on the center of the first wafer 100. Furthermore, the laser beam LB1 is emitted onto the separation-promoting film 138 throughout a region ranging from the outer periphery of the first wafer 100 to an intermediate position on the radius, and the separation-promoting film 138 is irradiated with the laser beam LB1 throughout a region in a ring (annular) shape along the outer periphery thereof. Due to the heat generated in the separation-promoting film 138, the separation-promoting film 138 and the insulating film 135, which are bonded with the less bonding strength, are separated as shown in FIG. 12C, and the first substrate 110 deforms into an upward warped shape together with the separation-promoting film 138.

According to the eleventh embodiment as well, the first substrate 110 may be deformed similarly to the first embodiment, and the first substrate 110 may be separated together with the separation-promoting film 138 at the interface between the insulating film 135 and the separation-promoting film 138 by performing the separating step. When separating, unlike the first embodiment, the separation-promoting film 138 separates from the insulating film 135, and the insulating film 135 remains bonded to the first devices 131 and the first front-surface film 132 in the first device layer 130 without separating.

Optionally, also in the second and seventh embodiments, the first wafer 100 may be configured to have the separation-promoting film 138, similarly to the eleventh embodiment, to perform the deforming step and the separating step with the separation-promoting film 138.

### Twelfth Embodiment

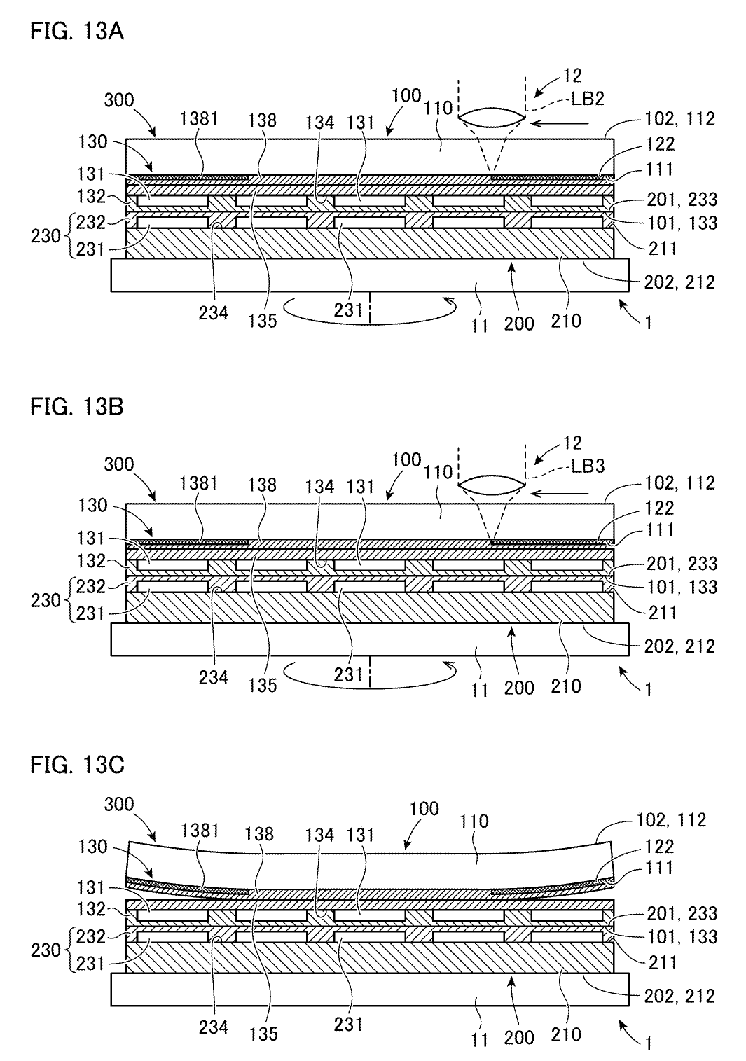

Next, a twelfth embodiment of the present disclosure will be described with reference to FIGS. 13A-13C. FIGS. 13A-13C are explanatory views of a deforming step in the method for processing a bonded wafer according to the twelfth embodiment. The twelfth embodiment is mainly different from the first embodiment in the configuration of the first wafer 100, formation of a lattice-defect layer 1381 in the deforming step, and the separating position of the first substrate 110.

The first wafer 100 in the twelfth embodiment, as shown in FIG. 13A, has the same configuration as the eleventh embodiment, where the first device layer 130 includes the separation-promoting film 138 laminated between the first substrate 110 and the insulating film 135. As such, the first device layer 130 includes the first devices 131, the insulating film 135, and the separation-promoting film 138 arranged in this order from the front surface 133.

### Deforming Step

In the deforming step of the twelfth embodiment, a lattice-defect layer 1381 is formed within the separation-promoting film 138 of the first device layer 130. The lattice-defect layer 1381 has a structure similar to the lattice-defect layer 136 of the second embodiment, except that the lattice-defect layer 1381 is formed in the separation-promoting film 138 rather than the insulating film 135.

In the deforming step of the twelfth embodiment as well, the laser emitter 12 emits a laser beam LB2 having the same wavelength K and output as those in the second embodiment onto the separation-promoting film 138. The laser beam LB2 is emitted onto the separation- promoting film 138 so as to form a spiral path centered on the center of the first wafer 100. Furthermore, the laser beam LB2 is emitted throughout a region ranging from the outer periphery of the first wafer 100 to an intermediate position on the radius, and the lattice-defect layer 1381 is formed within the separation-promoting film 138 as shown in FIG. 13A. The lattice-defect layer 1381 is formed in a region in a ring (annular) shape along the outer periphery of the first wafer 100 (separation-promoting film 138) in a view from above.

In the deforming step of the twelfth embodiment, as shown in FIG. 13B, a laser beam LB3 having the same wavelength K and output as those in the second embodiment is emitted from the laser emitter 12 onto the separation-promoting film 138. The laser beam LB3 is emitted similarly to the laser beam LB2, onto the separation-promoting film 138 within a region in a ring (annular) shape along the outer periphery of the separation-promoting film 138, that is, in the region where the lattice-defect layer 1381 is formed. Accordingly, the separation-promoting film 138 is heated, and by this heat, the first substrate 110 is deformed as shown in FIG. 13C. Due to this deformation, the separation-promoting film 138 and the insulating film 135 are separated, and the first substrate 110 deforms into an upward warped shape together with the separation- promoting film 138.

According to the twelfth embodiment as well, the first substrate 110 may be deformed similarly to the eleventh embodiment, and the first substrate 110 may be separated together with the separation-promoting film 138 at the interface between the insulating film 135 and the separation-promoting film 138 by performing the separating step.

### Thirteenth Embodiment

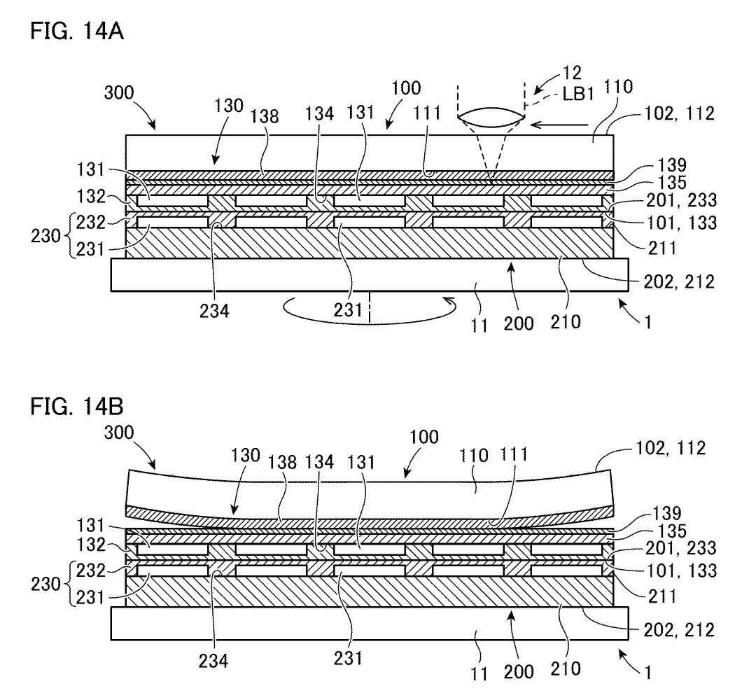

Next, a thirteenth embodiment of the present disclosure will be described with reference to FIGS. 14A-14B. FIGS. 14A-14B are explanatory views of a deforming step in the method for processing a bonded wafer according to the thirteenth embodiment. In the thirteenth embodiment, the configuration of the first wafer 100 is modified from that of the first embodiment. Furthermore, in the thirteenth embodiment, the irradiation position with the laser beam LB1 in the deforming step and the separating position of the first substrate 110 are modified from those of the first embodiment.

The first device layer 130 of the first wafer 100 in the thirteenth embodiment includes the separation-promoting film 138 and a metal film 139 that are laminated between the first substrate 110 and the insulating film 135, as shown in FIG. 14A. The first device layer 130 includes the first devices 131, the insulating film 135, the metal film 139, and the separation- promoting film 138 arranged in this order from the front surface 133, where the metal film 139 is laminated between the insulating film 135 and the separation-promoting film 138. The metal film 139 may be formed of the same material as the metal film 142 of the eighth embodiment, and a bonding strength between the metal film 139 and the separation-promoting film 138 is less than a bonding strength between the metal film 139 and the insulating film 135.

In the deforming step of the thirteenth embodiment, the laser emitter 12 emits a laser beam LB 1 having the same wavelength K and output as those in the first embodiment onto themetal film 139, thereby heating the metal film 139. The laser beam LB1 is emitted onto the metal film 139 so as to form a spiral path centered on the center of the first wafer 100. Furthermore, the laser beam LB1 is emitted onto the metal film 139 throughout a region ranging from the outer periphery of the first wafer 100 to an intermediate position on the radius, and the metal film 139 is irradiated with the laser beam LB1 in a region in a ring (annular) shape along the outer periphery thereof. Due to the heat generated in the metal film 139, the metal film 139 and the separation-promoting film 138, which are bonded with the less bonding strength, are separated as shown in FIG. 14B, and the first substrate 110 deforms into an upward warped shape together with the separation-promoting film 138.

According to the thirteenth embodiment as well, the first substrate 110 may be deformed similarly to the first embodiment, and the first substrate 110 may be separated together with the separation-promoting film 138 at the interface between the metal film 139 and the separation-promoting film 138 by performing the separating step.

Furthermore, by changing the position to form the metal film 142, 139 on the first wafer 100, or by selecting to form or not form the separation-promoting film 138, as in the eighth or thirteenth embodiment, a desired processed outcome, whether the metal film 139 is left unremoved or the metal film 142 is removed, may be selected. Note that, in the eighth and the thirteenth embodiments as well, at least the first substrate 110 is separated from the second wafer 200. In other words, the metal film 139 formed between the insulating film 135 and the separation-promoting film 138 in the thirteenth embodiment may optionally be formed between the first substrate 110 and the separation-promoting film 138.

### Fourteenth Embodiment

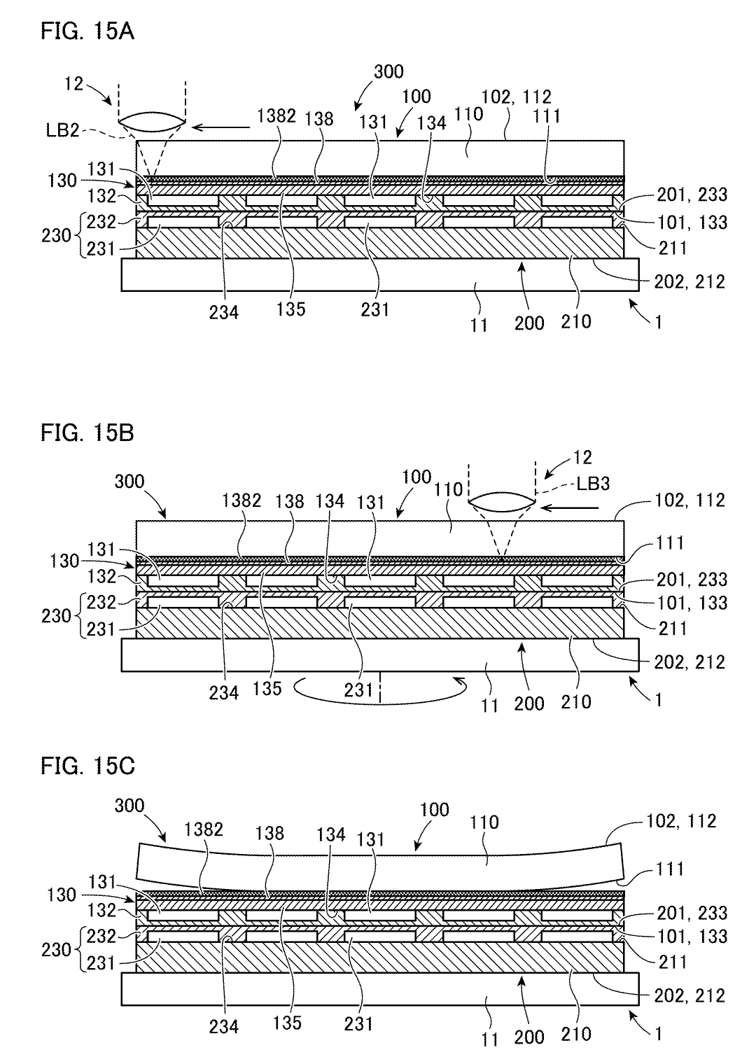

Next, a fourteenth embodiment of the present disclosure will be described with reference to FIGS. 15A-15C. FIGS. 15A-15C are explanatory views of steps in the method for processing a bonded wafer according to the fourteenth embodiment: FIG. 15A is an explanatory view of a lattice-defect layer forming step, and FIGS. 15B-15C are explanatory views of a deforming step. The fourteenth embodiment is mainly different from the first embodiment in the configuration of the first wafer 100, the lattice-defect layer forming step being performed before the deforming step, and the separating position of the first substrate 110 in the deforming step.

The first wafer 100 in the fourteenth embodiment, as shown in FIG. 15A, has the same configuration as the eleventh embodiment, where the first device layer 130 includes the separation-promoting film 138 laminated between the first substrate 110 and the insulating film 135. As such, the first device layer 130 includes the first devices 131, the insulating film 135, and the separation-promoting film 138 arranged in this order from the front surface 133.

### Lattice-Defect Layer Forming Step

In the lattice-defect layer forming step, a lattice-defect layer 1382 is formed inside the separation-promoting film 138 of the first device layer 130. The lattice-defect layer 1382 has a similar structure to the lattice-defect layer 137 of the ninth embodiment, except that the lattice- defect layer 1382 is formed in the separation-promoting film 138 rather than the insulating film 135.

In the lattice-defect layer forming step, the laser emitter 12 emits a laser beam LB2 having the same wavelength K and output as those in the second and ninth embodiments onto the separation-promoting film 138. The laser beam LB2 is emitted onto the separation-promoting film 138 so as to form a spiral path centered on the center of the first wafer 100. Furthermore, the laser beam LB2 is emitted over substantially the entire range of the separation-promoting film 138 extending from the outer periphery to the center of the first wafer 100. Therefore, as shown in FIG. 15A, a planar lattice-defect layer 1382 is formed within the separation-promoting film 138; in other words, substantially the entire area of the surface on the upper side in FIG. 15A (back surface side) of the separation-promoting film 138 is modified into the lattice-defect layer 1382.

### Deforming Step

In the deforming step of the fourteenth embodiment, as shown in FIG. 15B, the laser emitter 12 emits a laser beam LB3 having the same wavelength K and output as those in the second and ninth embodiments onto the separation-promoting film 138. The laser beam LB3 is emitted onto the separation-promoting film 138 so as to also form a spiral path centered on the center of the first wafer 100. Furthermore, the laser beam LB3 is emitted onto the separation- promoting film 138 throughout a region ranging from the outer periphery of the first wafer 100 to an intermediate position on the radius, and the separation-promoting film 138 is irradiated with the laser beam LB3 in a region in a ring (annular) shape along the outer periphery thereof. Accordingly, the separation-promoting film 138 is heated, and by this heat, the first substrate 110 is deformed as shown in FIG. 15C. Due to this deformation, the first substrate 110 separates from the lattice-defect layer 1382 of the separation-promoting film 138, and the first substrate 110 is deformed into an upward warped shape.

According to the fourteenth embodiment as well, the first substrate 110 may be deformed similarly to the ninth embodiment, and by performing the separating step, the first substrate 110 alone may be separated at the interface between the lattice-defect layer 1382 of the separation-promoting film 138 and the first substrate 110. When separating, unlike the eleventh embodiment, the first substrate 110 separates from the separation-promoting film 138, and the separation-promoting film 138 remains bonded to the first device layer 130 without separating. Note that embodiment of the present disclosure may not necessarily be limited to the configurations described above but may be modified in various ways. In the embodiments described above, sizes or forms of the components illustrated in the accompanying drawings are not limited thereto but may be modified optionally within the scope of the effects of the present disclosure. Moreover, the embodiment may be modified optionally without departing from the scope of the object of the present disclosure.

For example, in the deforming step of the thirteenth embodiment, rather than heating the metal film 139 by irradiation with the laser beam LB1, any one of the deforming steps of the first, second, third, sixth, seventh, eleventh, and twelfth embodiments may be performed to deform the first substrate 110.

For another example, in the deforming step of the eighth embodiment, rather than heating the metal film 142 by irradiation with the laser beam LB1, any one of the deforming steps of the first, third, sixth, and seventh embodiments may be performed to deform the first substrate 110.

For another example, in the above embodiments, the second wafer 200 may have a configuration where the second device layer 230 including the plurality of second devices 231 and the second front-surface film 232 is omitted. For another example, further, an insulating film similar to the insulating film 135 of the first device layer 130 may be formed in the second device layer 230 of the second wafer 200.

Moreover, the first through fourth and sixth through ninth embodiments illustrated the deforming steps where the laser beams LB1-LB4 are emitted so as to form the spiral path; however, the irradiation path with the laser beam is not necessarily limited to the spiral form. For example, the laser beam may be emitted to form a plurality of concentric paths centered on the center of the first substrate 110, a plurality of paths aligning linearly in parallel to one another, a plurality of wavy lines aligning side by side, paths in zigzags, or paths in various other forms. Furthermore, in the deforming step of the respective embodiments, the positions of the first substrate 110, between which the difference is created in the direction intersecting with the planar direction of the first substrate 110 (thickness direction) to cause the deformation, are not limited to the outer periphery, which is on the one side in the planar direction of the first substrate 110, and the center, which is on the other side in the planar direction. For example, one end of a diameter of the first substrate 110 may be the one side in the planar direction of the first substrate 110, and the other end of the diameter of the first substrate 110 may be the other side in the planar direction of the first substrate 110. In this setting, in the deforming step, the deformation may be achieved by creating a difference between positions in the thickness direction such that the position on the one side in the thickness direction warps upward while the position on the other end side of the first substrate 110 remains unchanged.

For another example, a separation trigger may be formed before performing the deforming step at a boundary between the first substrate 110 and the second wafer 200. The separation trigger may be formed by processing an outer peripheral portion of the first substrate 110. For example, a tip of a needle may be wedged into the outer edge of the first substrate 110 to form the separation trigger.

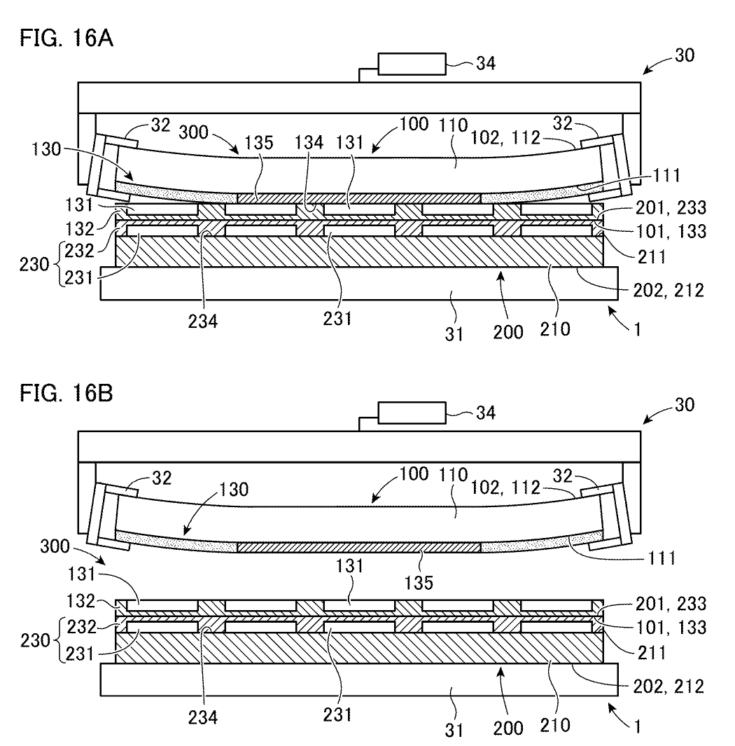

For another example, in the separating step, the first substrate 110 of the first wafer 100 may be separated from the second wafer 200 using a separating apparatus 30 (separating unit) shown in FIGS. 16A-16B. The bonded wafer 300 is conveyed and held on the chuck table 31 of the separating apparatus 30, and thereafter, the outer periphery of the first substrate 110 that warped upward from the insulating film 135 in the deforming step is clamped from both sides in the thickness direction and held by gripping chucks 32 (see FIG. 16A). The plurality of gripping chucks 32 are arranged at positions along the outer circumferential direction of the first wafer 100; in other words, the first substrate 110 is held by the plurality of gripping chucks 32 at a plurality of positions on the outer periphery.

Thereafter, as shown in FIG. 16B, the gripping chucks 32 are lifted via a lifting mechanism 34, and a force to pull the first wafer 100 apart from the second wafer 200 is applied. Accordingly, with the separating apparatus 30 of FIGS. 16A-16B as well, the front surface 111 of the first substrate 110 is removed and separated from the insulating film 135 on the bonded wafer 300.

Optionally, in the separating step, a holding table having a suction surface to hold the back surface 112 of the first substrate 110 by suction may be used to separate the first substrate 110 held on the holding table from the second wafer 200. For another example, in the separating step, ultrasonic vibrations may be applied to the first substrate 110. For another example, furthermore, in the separating step, ultrasonic water or high-pressure air may be jetted between the surfaces to be separated.

As explained above, the present disclosure has the effect that the separating position of the first substrate may be set at, for example, the interface between the insulating film and the first device layer, thereby eliminating the need for polishing to flatten the surface of the bonded wafer exposed after separation, and thus improving productivity.

What is claimed is:

1. A method for processing a bonded wafer where a first wafer, in which a first device layer including first devices and an insulating film arranged in this order from a front surface side is formed on a front surface of a first substrate, and a second wafer are bonded, to transfer the first devices to the second wafer by separating at least the first substrate, the method comprising:
a deforming step including deforming at least the first substrate such that a position on one side of the first substrate and a position on the other side of the first substrate in a planar direction are different in a direction intersecting with the planar direction, and
a separating step including, after the deforming step, separating at least the first substrate leaving the first devices on the second wafer.

2. The method according to claim 1, wherein the first wafer includes a separation- promoting film between the insulating film and the first substrate.

3. The method according to claim 1, wherein the first wafer includes a metal film between the insulating film and the first substrate.

4. The method according to claim 2, wherein the first wafer includes a metal film between the insulating film and the separation-promoting film.

5. The method according to claim 2, wherein the first wafer includes a metal film between the separation-promoting film and the first substrate.

6. The method according to claim 1, further comprising a lattice-defect layer forming step including forming a planar lattice-defect layer within the insulating film by emitting a laser beam onto the insulating film.

7. The method according to claim 2, further comprising a lattice-defect layer forming step including forming a planar lattice-defect layer within the separation-promoting film by emitting a laser beam onto the separation-promoting film.

8. The method according to claim 1, wherein the deforming step includes deforming the insulating film by emitting a laser beam onto the insulating film and thereby heating the insulating film.

9. The method according to claim 2, wherein the deforming step includes deforming the separation-promoting film by emitting a laser beam onto the separation-promoting film and thereby heating the separation-promoting film.

10. The method according to claim 1, wherein the deforming step includes:
forming a lattice-defect layer in a ring shape within the insulating film by emitting a laser beam having a transmissive wavelength onto the insulating film; and
deforming the lattice-defect layer by emitting the laser beam onto the lattice-defect layer and thereby heating the lattice-defect layer.

11. The method according to claim 2, wherein the deforming step includes:
forming a lattice-defect layer in a ring shape within the separation-promoting film by emitting a laser beam having a transmissive wavelength onto the separation-promoting film; and
deforming the lattice-defect layer by emitting the laser beam onto the lattice-defect layer and thereby heating the lattice-defect layer.

12. The method according to claim 1, wherein the deforming step includes thermally deforming the first substrate by emitting a laser beam having an absorptive wavelength onto the first substrate and thereby heating the first substrate.

13. The method according to claim 1, wherein the deforming step includes deforming the first substrate by:
emitting a laser beam having a transmissive wavelength onto the first substrate, and
forming a modified layer within the first substrate.

14. The method according to claim 1, wherein the deforming step includes deforming the first substrate by performing:
a surface-heating step including emitting a laser beam having an absorptive wavelength onto the first substrate and thereby heating a surficial part of the first substrate; and
a cooling step including cooling the surficial part of the first substrate having been heated in the surface-heating step.

15. The method according to claim 1, wherein the deforming step includes deforming the first substrate by cooling a back surface of the first substrate partially.

16. The method according to claim 3, wherein the deforming step includes deforming the metal film by emitting a laser beam onto the metal film and thereby heating the metal film.

17. A processing apparatus configured to process a bonded wafer where a first wafer, in which a first device layer including first devices and an insulating film arranged in this order from a front surface side is formed on a front surface of a first substrate, and a second wafer are bonded, to transfer the first devices to the second wafer by separating the first substrate, comprising:
a chuck table configured to hold the second wafer in the bonded wafer;
a deforming unit configured to deform at least a part of the first substrate of the first wafer in the bonded wafer; and
a separating unit configured to separate the deformed first substrate from the bonded wafer.

18. The processing apparatus according to claim 17, wherein the deforming unit includes a temperature-difference creating unit configured to create a temperature difference between the first wafer and the second wafer by performing at least one of heating or cooling to one of the first wafer and the second wafer.

19. The processing apparatus according to claim 18, wherein the temperature-difference creating unit includes a laser unit configured to emit a laser beam onto the first wafer and thereby heating the first substrate.

20. The processing apparatus according to claim 18, wherein the temperature-difference creating unit includes a heater unit configured to heat the first wafer.

21. The processing apparatus according to claim 18, wherein the temperature-difference creating unit includes a cooling unit configured to cool the first wafer.
